(19) United States
(12) Patent Application Publication
(10) Pub. No.: US 2015/0245548 A1
(43) Pub. Date: Aug. 27, 2015

(54) CONTROL OF ELECTRIC FIELD EFFECTS IN A PRINTED CIRCUIT BOARD ASSEMBLY USING EMBEDDED NICKEL-METAL COMPOSITE MATERIALS

(71) Applicant: Sparton Corporation, Schaumburg, IL (US)

(72) Inventors: Lendon L. Bendix, Deland, FL (US); Derek Turner, Winter Park, FL (US)

(73) Assignee: Sparton Corporation, Schaumburg, IL (US)

(21) Appl. No.: 14/190,627

(22) Filed: Feb. 26, 2014

(51) Int. Cl. H05K 9/00; H05K 7/02

(52) U.S. Cl. CPC H05K 9/0088; H05K 7/02

(57) ABSTRACT

A printed circuit board assembly (PCBA) controls an electrically-initiated device (EID) in an electric field. The PCBA includes a conductive layer, a dielectric layer, and a trans-conductive layer (TCL). The PCBA has one or more designated protected areas. An electrical current with a predetermined current density is present in the conductive layer when the PCBA is placed in the electric field. The TCL is constructed of a nickel-metal composite metamaterial positioned between the conductive and dielectric layers. The TCL has a variable geometry with respect to at least one of the thickness, width, and length of the PCBA, and compresses in proportion to an energy level of the electric field to direct the electrical current away from the designated protected area(s). A system includes a housing, a power supply, an EID such as a sonobuoy or medical device, and the PCBA, all of which are encapsulated in the housing.

### TECHNICAL FIELD

The present disclosure relates to the control of electric field effects in a printed circuit board assembly using embedded nickel-metal composite materials.

### BACKGROUND

Silicon and other semiconductor materials are used to construct printed circuit board assemblies (PCBAs) for use in the control of electronic circuits and other devices. In a typical PCBA, conductors and circuit components such as capacitors, resistors, diodes, and the like may be surface mounted or etched onto the PCBA. The PCBA supports as well as electrically interconnects the various components and traces using thin sheets of conductive foil interposed between dielectric layers.

PCBAs, being electric circuits, Lend to be highly sensitive to the effects of radiation. Therefore, a common board-level design feature is a Faraday cage. Faraday cages are metal enclosures that are typically surface mounted to the PCBA between sensitive circuit components and the source of radiation. Such cages form electromagnetic interference (EMI) shields around the protected components, and operate by reflecting radiation energy and/or dissipating the energy as heat. However, Faraday shields and other EMI shielding techniques may not be appropriate in certain applications due to their size and weight, as well as their shielding-based principle of operation.

### SUMMARY

A printed circuit board assembly (PCBA) and an associated system are disclosed herein. Unlike Faraday cages and other EMI shielding approaches of the type described above, the present invention embeds one or more trans-conductor layers (TCLs) of a nickel-metal composite material in the layers or traces of the PCBA. The TCL acts a filter of broadband direct-radiated radio frequency (RF) and complex resonant electrical fields. The embedded materials, which are provided with a variable geometry, i.e., geometric shape, with respect to the PCBA's length, width, and/or height, absorb the incident energy in a particular bandwidth and also prevent dissipation of this absorbed energy to specific designated “protected” portions of the PCBA. The energy dissipates in two ways: as heat via thermal conductance within the PCBA, and via reactance, i.e., by dissipation of the energy into the surrounding dielectric material.

Faraday cages and other prior art EMI shields act quite differently. For example, Faraday shields can be relatively large and bulky relative to the components that are being protected. As a result, physical EMI shields typically add an undesirable height or Z-dimension that may be less than optimal or even impracticable for certain applications, particularly those encapsulated in a housing having limited internal space. Additionally, incident field energy may be impinged within any cavities that might exist between the EMI shield and the protected components of the PCBA, thereby leading to undesirable cavity effects. This too may be undesirable in certain sensitive applications.

Electrically-initiated devices (EIDs) are a particular class of sensitive devices that may benefit from the present invention. Such devices are electrically initiated, i.e., triggered or activated via an internally or externally generated electrical signal, often while being exposed to external electric fields of varying intensities. Impressed or conducted energy could result in an inadvertent or premature activation of EID. Faraday cages and EMI shielding in general may have a limited effect in such applications. Something more than the conventional EMI shielding techniques of the known art is required for the protection of EIDs. It is therefore a goal of the present invention to solve this particular problem.

In an example embodiment, the PCBA is provided for control of an EID in an electric field. The PCBA includes a conductive layer, a dielectric layer, and a trans-conductor layer (TCL) constructed of a nickel-metal composite material. A current flow having a predetermined current density is present in the conductive layer, with this current density resulting from irradiation of the PCBA by the electric field. The TCL is positioned between the conductive and dielectric layers, and along with those layers provides the PCBA with its thickness, width, and length dimensions. The TCL, which has a variable geometry with respect to at least one of these dimensions, i.e., has a thickness, width, and/or length that is nonuniform along the length and/or width of the PCBA, compresses in proportion to an energy level of the electric field falling incident upon the PCBA to thereby direct the current flow away from a designated protected area or areas of the conductive layer.

The TCL may be constructed partially of nickel-phosphorous (NiPh) in an example embodiment. Nickel-chromium (NiCr) may be used in another embodiment. Other materials may be conceived of within the intended scope of the invention, with the properties of nickel being particularly useful for achieving the desired ends. The nickel content of the TCL may range from about 10%-45% by total weight of the TCL for optimal results, with the significance of this range explained further herein.

An associated system is also disclosed herein. The system includes a housing, a power supply, an EID, and the PCBA described above. The power supply, the EID, and the PCBA are all encapsulated within the housing, with the EID and the PCBA being electrically connected to the power supply, e.g., a DC battery. The design of the PCBA prevents an unintended activation of the EID due to the electric field and the flow of current at the predetermined current density in the conductive layer.

The above features and advantages and other features and advantages of the present invention are readily apparent from the following detailed description of the best modes for carrying out the invention when taken in connection with the accompanying drawings.

### BRIEF DESCRIPTION OF THE DRAWINGS

FIG. 1 is a schematic perspective view illustration of an example system having a printed circuit board assembly (PCBA) contained therein, with the PCBA constructed with embedded nickel-metal trans-conductor layers as set forth herein.

FIG. 2 is schematic cross-sectional view of a PCBA usable within the system shown in FIG. 1.

FIG. 2A is a schematic plan view illustration of a portion of the PCBA of FIG. 2 in a possible embodiment.

FIG. 3 is a flow chart describing a method of constructing the PCBA shown in FIG. 1.

### DETAILED DESCRIPTION

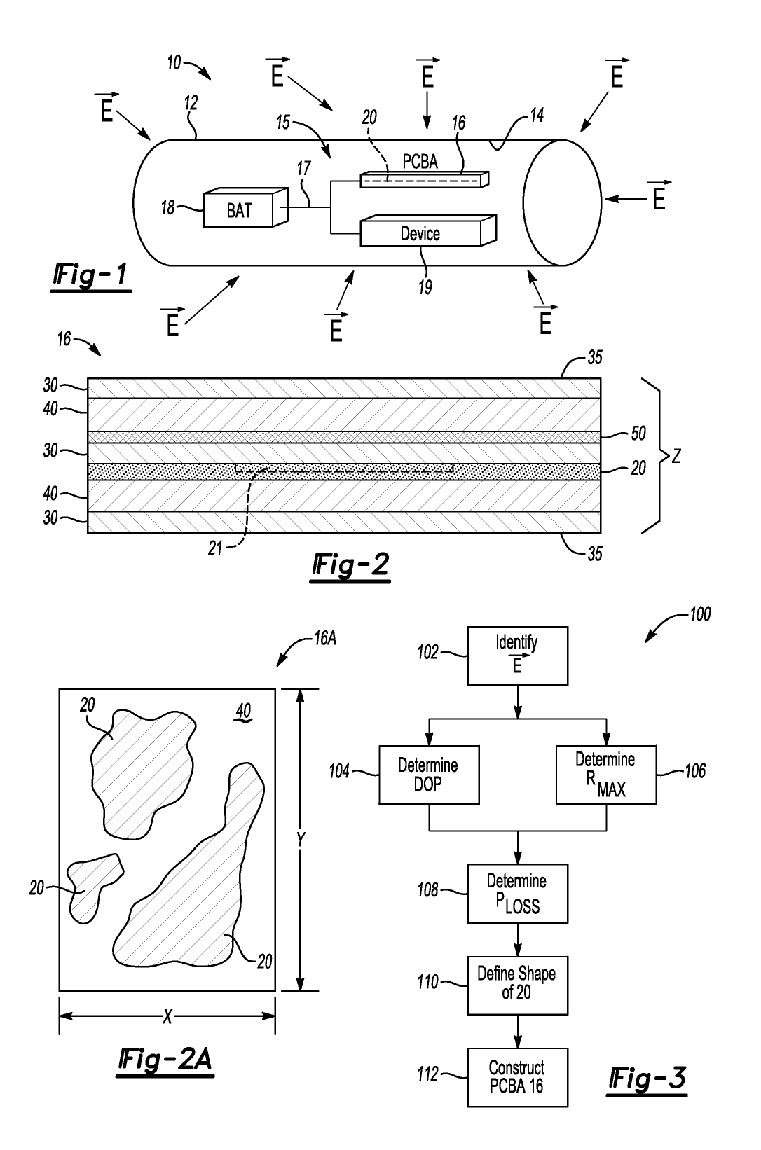

Referring to the drawings, wherein like reference numbers correspond to like or similar components throughout the several figures, a system 10 is shown schematically in FIG. 1. The system 10 includes a housing 12 having a wall 14 that defines an internal cavity 15. While shown as an example cylinder, e.g., the shape typically assumed by the housing 12 when used in an example sonobuoy application, the actual shape of the housing 12 may be expected to differ with the design. For instance, the system 10 may be alternatively embodied as a medical device such as a pacemaker, and thus may have a rectangular or an irregular shape. Other geometric shapes may be envisioned without departing from the intended inventive scope.

A printed circuit board assembly (PCBA) 16 is encapsulated within the cavity 15, along with other possible components such as a power supply 18 such as a DC battery (BAT) and an electrically-activated device (EID) 19. The PCBA 16 and the EID 19 are electrically connected to the power supply 18 via a conductor 17, for instance a length of wire. Example EIDs 19 may include the sonobuoy and medical devices noted above.

Sonobouys, as is well known in the art, are submarine, air, or surface-launched devices that are used to detect acoustic emissions or reflections in a body of water, and to transmit the detected signals to a remote source for processing. Sonobuoys may employ acoustic sensors that aid in the detection, classification, and localization of targets in the body of water via determination of sonar propagation properties and acoustic range prediction. Thus, the EID 19 of FIG. 1 could be a launch device or other controlled component of such a sonobuoy. Example medical devices that may embody the EID 19 of FIG. 1 include those used in critical care systems such as pacemakers, defibrillators, neuro-stimulator devices, and robotic surgical tools. While sonobuoys and medical devices are examples of systems 10 that may benefit from the design of the PCBA 16 disclosed herein, the system 10 is not intended to be limited to such devices.

In general, the PCBA 16 of FIG. 1 may be constructed using, for instance, surface and/or bulk micromachining techniques such as chemical vapor deposition, etching, and/or other suitable processes, as is well understood in the art. The PCBA 16, the internal structure of which is described in further detail below with reference to FIG. 2, is a multi-layered circuit board. The various layers may be laminated together via pressure and heat to form the PCBA 16 as an integral piece.

As at least one of the traces or layers, the PCBA 16, in all of its embodiments, includes an embedded trans-conductor layer (TCL) 20. As explained in detail below, the TCL 20 is an embedded layer of a nickel-metal composite metamaterial, i.e., artificial materials that are structured on a size scale that is smaller than the wavelength of external stimuli, e.g., nanomaterials. Such materials may exhibit properties that are not typically found in nature. One such property used herein is the tendency to compress in the presence of energy from an externally-generated electric field, which is represented schematically in FIG. 1 by arrows \vec{E}. The geometry of the TCL 20 may also vary with respect to at least one of the three primary dimensions of the PCBA 16, i.e., length, width, and height. That is, TCL 20 could be thicker, wider, or longer in certain locations relative to others.

The TCL 20 as described herein is configured to act as a filter of broad-band energy from the externally-generated electric field \vec{E}. As used herein, the term “broad-band” refers to a sufficiently wide range of radio frequency (RF) energy, e.g., 2 MHz-20 GHz in an example embodiment, and any complex resonant fields associated with this energy. It is recognized herein that the electric field \vec{E} may induce a current with a current density J in the PCBA 16. The term “current density” refers to the electric current (I) per unit area (A) of cross section. The magnitude of the current density J, as measured in amperes/m², may be given as:

$$J = {lim}_{A \to 0} \frac{I}{A}$$

In particular, the TCL 20 of the present invention is shaped, sized, and positioned, i.e., configured, to direct undesirable energy from the electric field \vec{E} through the PCBA 16 without penetrating into an any conductive layers. The TCL 20 is embedded in the PCBA 16 itself, and thus unlike Faraday cages and other EMI shielding designs does not cover the PCBA 16. Likewise, the TCL 20 does not reflect energy away from the PCBA 16 like a Faraday shield, and also does not suffer from the same Z-dimensional packaging issues of such shields.

A key element of the present invention is the use of nickel in the TCL 20 in a particular manner, which is to control the undesirable effects of the electric field \vec{E}. The TCL 20, due to its nickel content, is configured to contract or otherwise change shape or deform in the presence of the electric field \vec{E}, which in turn allows the TCL 20 to be formed with a variable geometry and thus control the effects of the electric field \vec{E} on the performance of the PCBA 16. The particular design of the TCL 20 is both field and application specific. A general approach for achieving the desired end results via the TCL 20 is described below with reference to FIG. 3.

As used herein, the term “nickel-metal composite” refers to any alloy of nickel, with nickel phosphorous (NiPh) and nickel chromium (NiCr) being two possible embodiments exhibiting desirable properties and control results. NiPh, for instance, is highly resistive, and in a field such as the electric field \vec{E}, exhibits a measurable frequency response. This response can be employed to the desired effect as explained below. An alloy having an excessive amount of nickel, however, tends to behave too much like a conductor, and therefore the percentage of nickel by weight should be limited. An example range that achieves the desired effect is 10-45% of nickel by weight of the TCL 20.

Additionally, the TCL 20 exhibits capacitance due in part to its surface roughness. For this reason, the TCL acts a transmission line, and for this reason is referred to herein as a Trans-Conductor Layer or TCL. In acting like a transmission line, the TCL 20 is able to reduce EMI effects from the externally-generated electric field \vec{E} via embedding of nickel-based meta materials in a purposeful, design-specific manner. The TCL 20 guides unwanted current density flow away from any predetermined sensitive protected areas of the PCBA 16, with energy dissipated away from such areas via thermal conductance and reactance. In this manner, the internal traces of the PCBA 16 are prevented from inadvertently acting as fuses in the presence of the electric field \vec{E}, thereby avoiding prematurely firing or triggering some action via the PCBA 16, such as an activation of the EID 19.

In the example system 10 shown in FIG. 1, the cavity 15 allows space for the PCBA 16 to be inserted in the housing 12 along with other necessary components, e.g., the power supply 18 and the EID 19. However, the same cavity 15 may serve to impinge energy from the electric field \vec{E}. Various cavity modes may result from this effect. Common cavity modes include coupling and cross-coupling, and thus traces of the PCBA 16 could pick up energy from the electric field \vec{E} or from energy trapped in the cavity 15, e.g., energy entering any external openings or passages of the housing 12.

Referring to FIG. 2, an example embodiment of the PCBA 16 of FIG. 1 is shown in a schematic cross-sectional view. The thickness or z-dimension of the PCBA 16 is formed from a laminated stack-up of layers 20, 30, 40, and 50, i.e., TCL(s) 20, conductive layer(s) 30, dielectric layer(s) 40, and pre-pregnated layer(s) 50. The PCBA 16 in all embodiments includes at least one conductive layer 30, such as thin foil sheet of copper or another suitable conductor.

Three conductive layers 30 are shown in the non-limiting example embodiment of FIG. 2, with a pair of the conductive layers 30 acting as outer layers of the PCBA 16 with outermost surfaces 35. Two dielectric layers 40 are shown in the same example embodiment, with the conductive outer layers 30 positioned adjacent to a corresponding one of the dielectric layers 40. The pre-pregnated layer 50 may be disposed between one of the conductive layers 30 and one of the dielectric layers 40.

Suitable materials for the dielectric layers 40 include epoxy-resin fiberglass or a glass-reinforced epoxy laminate, e.g., FR-4, or any other application-suitable material. The pre-pregnated layer 50 may be formed as an uncured resin-treated glass or ceramic sufficient for filling any gaps or spacing between the outer layers, i.e., conductive layers 30 having the outermost surfaces 35. Use of the pre-pregnated layer(s) 50 may help to bond the various layers 20, 30, and 40 together, and also providing additional structural integrity for the PCBA 16.

While the layers 20, 30, and 40 are shown with uniform distribution in FIG. 2 for illustrative clarity, the TCL 20 in an actual application will ordinarily have a variable geometry with respect to at least one of the thickness (z-dimension), width (x-direction), and length (y-direction) of the PCBA 16. An example of this variable geometry is shown via narrowed portion 21 in FIG. 2, which indicates z-dimension or thickness variation. A PCBA portion 16A is shown in the schematic plan view of FIG. 2A to show geometric variation with respect to the width/x-dimension and length/y-dimension of the PCBA 16 of FIG. 2. In FIG. 2A, the first four layers 30, 40, 50, and 30 of FIG. 2 are removed for illustrative clarity.

Referring to FIG. 3, an example method 100 is shown that explains a process for designing and manufacturing a PCBA such as the PCBA 16 of FIG. 2 for use as an EMI broadband filter using the trans-conductor properties of the TCL 20 described above. The method 100 begins with step 102, wherein the electric field \vec{E} is identified. Step 102 entails determining the type and intensity of the electric field \vec{E}, e.g., the far field, near far field, and near reactive field, as well as the polarization of these fields. Step 102 also includes determining the band of frequencies of exposure, whether broad, narrow, pulsed, or continuous.

After this is complete, the components of the PCBA 16 are identified that are susceptible to the identified properties of the electric field \vec{E}. These components are referred to hereinafter as the predetermined protected components. Example components can include traces, embedded vias, through vias, connectors, ribbon cable, wires, and the like. The method 100 proceeds to steps 104 and 106 when all of this is completed.

At step 104, the method 100 includes determining the depth of penetration (DOP) of the expected portions of the electric field \vec{E} into the identified predetermined protected components from step 102. The end goal of step 104 is to determine the thickness of the TCL 20, which should be sufficient for conducting the required electrical current from the electric field \vec{E} having a predetermined current density J. The method 100 then proceeds to step 108.

Step 106, which is performed in tandem with step 104, includes determining the maximum allowable resistance (R_{MAX}) of the circuit trace being formed by the TCL 20. The circuit embodied as the PCBA 16 has an overall maximum resistance for implementation of the desired application, including control of the EID 19 of FIG. 1. The sheet resistance of the TCL 20 can be used to calculate the effective added impedance of the TCL 20 to the overall PCBA 16. The location of placement of the TCL 20 is also determined as part of step 106 using this information, with the electrical current I with the predetermined current density J directed around any protected components as noted above. The method 100 then proceeds to step 108.

Step 108 entails determining the power loss (P_{LOSS}) in the PCBA 16. Step 108 may entail solving the following equation:

$${P}_{LOSS} = 2 ( \frac{{R}_{S}}{2} ) {\int }_{x = 0}^{∞} {\ddot{J}}_{S}^{2} d x$$

where R_{S} is the sheet resistance and J_{S} is the current density of the current flowing the TCL 20. The impressed and conducted current densities are also determined, with impressed current being the current due to radiation from the electric field \vec{E} and the conducted current being the current due to any adjacent sources. The required maximum attenuation for controlling the current density J resulting from the electric field \vec{E} is ultimately determined as part of step 108. As the TCL 20 is not purely a capacitor, nor is it purely an inductor or a resistor, the embedded TCL 20 will change its impedance in the presence of the electric field \vec{E}. That is, the TCL 20 will react over a very broad band range of frequencies with variable attenuation. The method 100 proceeds to step 110 once the power loss and maximum attenuation have been determined.

Step 110 includes defining the shape of the TCL 20. This includes defining the length, width, and thickness of the TCL 20. For commercially available sheets of NiPH, for example, market standard sheet resistance R_{S} is 10, 25, and 250 Ohms/meter, with various sheet thicknesses. For any of the suitable nickel-metal based materials used for construction of the TCL 20, as the magnetic field increases the nickel will contract. Although the nickel contracts, there is more phosphorous, in the example of NiPh, so the surface roughness of the TCL 20 will change with the contraction. This in turn changes the capacitance and changes the effective permittivity of the dielectric material located adjacent to the TCL 20, for instance the dielectric layer 40 shown at that location in FIG. 2. Although the TCL 20 is not a pure resistor, the TCL 20 has various resistance values under varying electric fields, effective wavelengths, and penetration depths. The method 100 proceeds to step 112 after the shape of the TCL 20 has been defined.

Step 112 includes constructing the TCL 20 with the determined shape from step 110. Constructing the TCL 20 with the desired shape may take place with the fabrication of the PCBA 16. The PCBA 16 thereafter can be installed in a system, such as the system 10 shown in FIG. 1, and used in the control of a given EID 19.

While the best modes for carrying out the invention have been described in detail, those familiar with the art to which this invention relates will recognize various alternative designs and embodiments for practicing the invention within the scope of the appended claims.

1. A printed circuit board assembly (PCBA) for control of an electrically-initiated device (EID) in a electric field, the PCBA comprising:
a conductive layer having at least one designated protected area, wherein an electrical current with a predetermined current density is present in the conductive layer when the PCBA is placed in the electric field;
a dielectric layer; and
a trans-conductor layer constructed of a nickel-metal composite material and positioned between the conductive and dielectric layers, wherein the conductive layer, the dielectric layer, and TCL provide the PCBA with a thickness, a width, and a length;
wherein the TCL has a variable geometry with respect to at least one of the thickness, width, and length of the PCBA, and compresses in proportion to an energy level of the electric field to thereby direct the electrical current with the current density away from the at least one designated protected area of the conductive layer.

2. The PCBA of claim 1, wherein the TCL is constructed of a nickel-phosphorous (NiPh) metamaterial.

3. The PCBA of claim 1, wherein the TCL is constructed of a nickel-chromium (NiCr) metamaterial.

4. The PCBA of claim 1, wherein the nickel content of the TCL is between about 10% and 45% by weight of the TCL.

5. The PCBA of claim 1, further comprising an additional conductive layer positioned immediately adjacent to the dielectric layer.

6. The PCBA of claim 1, further comprising a pre-pregnated layer positioned immediately adjacent to the conductive layer, and an additional dielectric layer positioned immediately adjacent to the pre-pregnated layer.

7. The PCBA of claim 6, further comprising a pair of conductive outer layers, wherein the conductive outer layers are positioned adjacent to a corresponding one of the dielectric layer and the additional dielectric layer, and together form outermost surfaces of the PCBA.

8. A system comprising:
a housing;
a power supply;
an electrically-initiated device (EID); and
a printed circuit board assembly (PCBA), wherein the EID, the power supply, and the PCBA are encapsulated within the housing, the EID and the PCBA are electrically connected to the power supply, and the PCBA includes:
a conductive layer having a designated protected area, wherein a current with a predetermined current density is present in the conductive layer in the presence of the electric field;
a dielectric layer; and
a trans-conductor layer (TCL) positioned between the conductive and dielectric layers, wherein the conductive layer, the dielectric layer, and the TCL provide the PCBA with a thickness, a width, and a length;
wherein the TCL has a variable geometry with respect to at least one of the thickness, width, and length of the PCBA, and compresses in proportion to the electric field to thereby direct the electrical current with the predetermined current density away from the designated protected area, thereby preventing an unintended activation of the EID.

9. The system of claim 8, wherein the EID is a sonobuoy.

10. The system of claim 8, wherein the EID is a medical device.

11. The system of claim 8, wherein the TCL is constructed of a nickel-phosphorous (NiPh) metamaterial.

12. The system of claim 8, wherein the nickel-metal composite layer is constructed of a nickel-chromium (NiCr) metamaterial.

13. The system of claim 8, wherein the nickel content of the TCL is between about 10% and 45% nickel by weight of the TCL.

14. The system of claim 8, further comprising an additional conductive layer positioned immediately adjacent to the dielectric layer.

15. The system of claim 8, further comprising a pre-pregnated layer positioned immediately adjacent to the conductive layer, and an additional dielectric layer positioned immediately adjacent to the pre-pregnated layer.

16. The system of claim 8, further comprising a pair of conductive outer layers, wherein the conductive outer layers are positioned adjacent to a corresponding one of the dielectric layer and the additional dielectric layer, and together form outermost surfaces of the PCBA.
